(19) United States
(12) Patent Application Publication
(10) Pub. No.: US 2008/0061385 A1
(43) Pub. Date: Mar. 13, 2008

(54) MANUFACTURING METHOD OF A SEMICONDUCTOR DEVICE

(76) Inventor: Sung-Joong Joo, Incheon (KR)

Correspondence Address: SHERR & NOURSE, PLLC, 620 HERNDON PARKWAY, SUITE 200, HERNDON, VA, 20170, US

(21) Appl. No.: 11/850,901

(22) Filed: Sep. 6, 2007

(30) Foreign Application Priority Data
Sep. 12, 2006 (KR) 10-2006-0087764

(51) Int. Cl. H01L 29/94; H01L 21/336

(52) U.S. Cl. 257/412; 438/299; 257/E29.345; 257/E21.409

(57) ABSTRACT

A manufacturing method of a semiconductor device including at least one of the following steps. Forming a gate insulating layer, a gate electrode layer, a spacer, a source region and a drain region on and/or over a substrate on which a predetermined lower structure is formed. Making the upper portion of the gate electrode layer and the upper portions of the source and the drain an amorphous structure using a pre-amorphization implant process. Removing the native oxide on the upper portion of the gate electrode layer and the upper portions of the source and the drain by performing a pre-cleaning process. Forming an oxide film on the upper portion of the gate electrode layer and the upper portions of the source and the drain. Forming a salicide layer on the upper portion of the oxide film

The present application claims priority under 35 U.S.C. 119 to Korean Patent Application No. 10-2006-0087764 (filed on Sep. 12, 2006), which is hereby incorporated by reference in its entirety.

### BACKGROUND

Aspects of semiconductor fabrication have focused on enhancing the integration of semiconductor devices (e.g., achieving smaller scale devices). Use of an impurity diffusion layer, i.e., a shallow junction of a source and a drain, may serve an important role in the development of smaller scale semiconductor devices. Shallow junctions can increase the resistance of the impurity diffusion layer, and thus, may have a bad effect on the operatability of a high density device.

Consequently, it has become necessary to use a self-aligned silicide (salicide) process in order to reduce the sheet resistance of the impurity diffusion layer. The salicide process may reduce the sheet resistance of the impurity diffusion layer by depositing a refractory metal such as cobalt and the like on and/or over the impurity diffusion layer and then siliciding the metal.

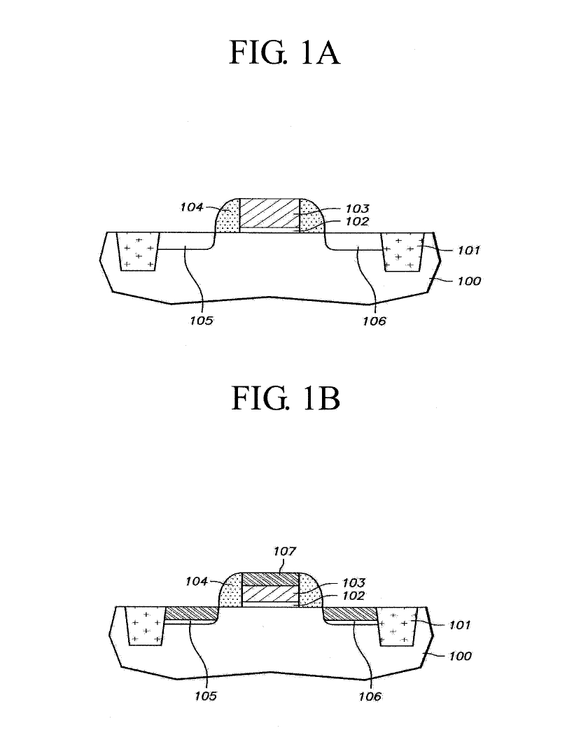

As illustrated in example FIG. 1A, isolating layer 101 may be formed on semiconductor substrate 100 and gate insulating layer 102 formed on and/or over an active region of substrate 100. A material layer for forming a gate including a polysilicon may deposited on and/or over gate insulating layer 102. The polysilicon may be selectively patterned to form gate electrode layer 103. A material layer for forming a side wall, for example, a CVD oxide film or a nitride film may be deposited and etched on and/or over semiconductor substrate 100 to form a gate side wall 104 on the side surfaces of gate electrode layer 103. An impurity may then be implanted into the source and drain forming area using an ion implant method to form source region 105 and drain region 106.

As illustrated in example FIG. 1B, metals such as cobalt (Co), titanium (Ti) and titanium nitride (TiN) are sequentially deposited on and/or over semiconductor substrate 100 and subjected to primary thermal processing to form a salicide layer. Non-reacted Co layer and Ti layer may be removed through a wet process and subjected to a secondary thermal process to form cobalt salicide (CoSi₂) layer 107.

The salicide process can achieve high-speed semiconductor devices of size 130 nm or less by reducing the sheet resistance of the impurity diffusion layer. The salicide process, however, has shortcomings. For instance, if a cobalt layer having a thickness of 130 nm is applied to a semiconductor device of 90 nm or less, an excessive silicide is formed in the process. This excess silicide combines a silicon (Si) atom from the impurity diffusion layer and an atom from the refractory metal which breaks the shallow junction, thereby causing an increase in the junction leakage current. The thickness of the salicide can be determined by the amount of native oxide existing on the upper portions of the gate, the source, and the drain.

### SUMMARY

Embodiments relate to a manufacturing method of a semiconductor device including at least one of the following steps: forming a gate insulating layer, a gate electrode layer, a spacer, a source region and a drain region on and/or over a substrate on which a predetermined lower structure is formed. Making the upper portion of the gate electrode layer and the upper portions of the source and the drain an amorphous structure using a pre-amorphization implant process. Removing the native oxide on the upper portion of the gate electrode layer and the upper portions of the source and the drain by performing a pre-cleaning process. Forming an oxide film on the upper portion of the gate electrode layer and the upper portions of the source and the drain. Forming a salicide layer on the upper portion of the oxide film.

### DRAWINGS

Example FIGS. 1A and 1B illustrate a manufacturing method of a salicide of a semiconductor device.

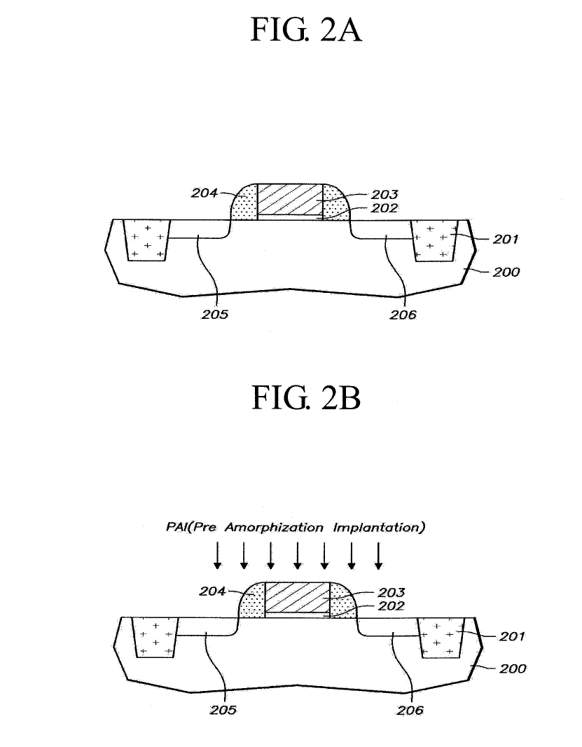

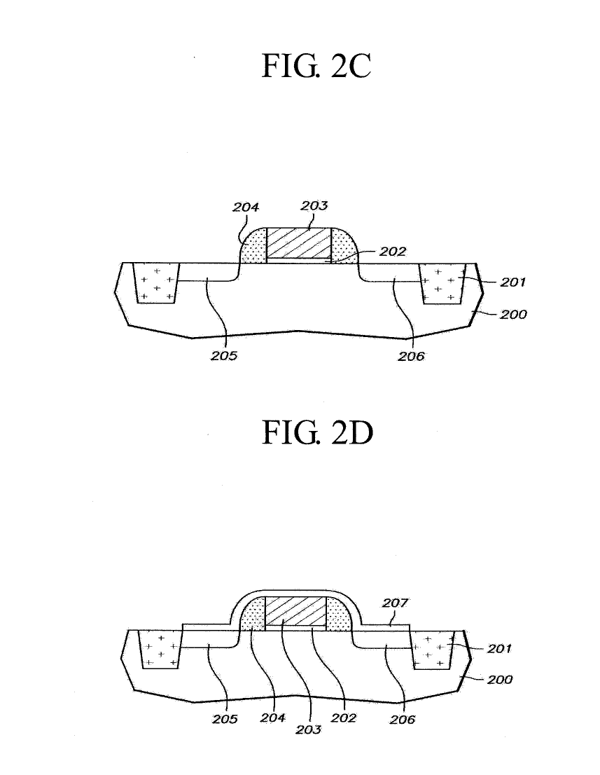

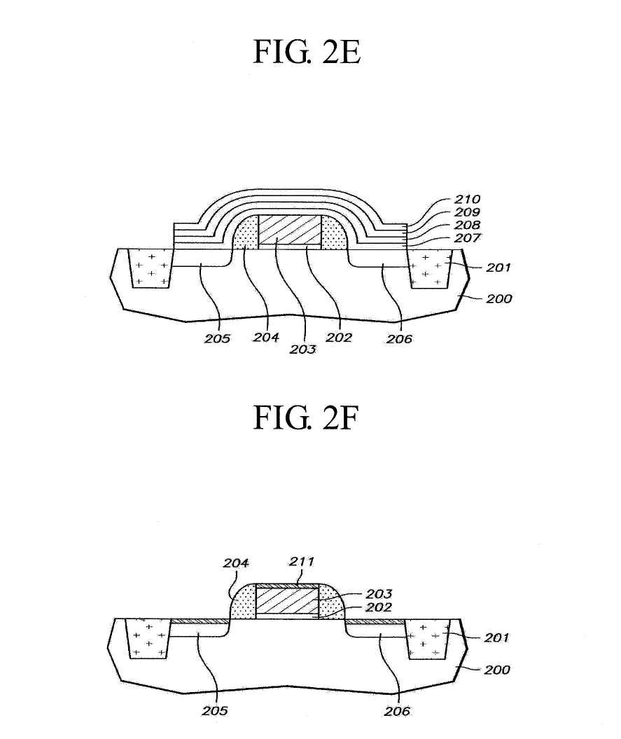

Example FIGS. 2A to 2F illustrate a method of a manufacturing method of a salicide of a semiconductor device, in accordance with embodiments.

### DESCRIPTION

As illustrated in example FIG. 2A, device isolating layer 201 may be formed on and/or over semiconductor substrate 200. Thereafter, gate insulating layer 202 may be formed on and/or over an active area defined by device isolating layer 201. A material layer composed of a polysilicon material for forming a gate may be deposited on and/or over gate insulating layer 202. The polysilicon material layer can be deposited using a CVD method. The deposited poly silicon may be selectively patterned to form gate electrode layer 203. A material layer for forming side walls may be deposited on and/or over semiconductor substrate 200. The side walls material layer for forming the side wall may be composed of an oxide and a nitride and may use a deposition method such as CVD. The sidewall material layer may be etched using a blanket etch process such as a blanket or an etch back without use of an etch mask on the upper portion of the overall structure. Both sides of the gate electrode layer 203 can be formed with a spacer 204 provided against side surfaces of gate insulating layer 202 and gate electrode layer 203. A Group III or Group V ion can be implanted using gate electrode layer 203 including the spacer 204 as a mask to form source region 205 and drain region 206.

As illustrated in example FIG. 2B, the crystal state of the silicon surface can be amorphized through a pre-amorphization implantation process using ions such as Ge, N₂, Ar or As and the like on and/or over the overall area of substrate 200 so that it is uniform.

As illustrated in example FIG. 2C, in order to form a subsequent salicide layer, a wet cleaning process may be performed on and/or over the substrate 200 using a HF solution to remove native oxide.

As illustrated in example FIG. 2D, oxide film 207 may be deposited at a thickness range of between 0 um to 8 um using a sequential repeat of an implant/exhaust using an atomic layer deposition (ALD). If oxide film 207 is deposited having a large thickness, it may result in the cobalt silicide layer being less thick than necessary since oxide film 207 prevents a Co layer from reacting to Si by diffusion. If oxide film 207 is deposited having a predetermined thickness, a corresponding thickness of a cobalt silicide layer may be known experimentally at a certain process condition. Consequently, the thickness of a cobalt silicide layer may be predicted by knowing a predetermined thickness of oxide film 207.

As illustrated in example FIG. 2E, Co layer 208, Ti layer 209, and TiN layer 210 may be sequentially formed on and/or over oxide film 207 using an ALD method. Ti layer 209 may be formed to function as a barrier layer for blocking the influence of oxygen when Co and Si are reacted during a thermal process and to control the reaction between Co and Si. If Ti layer 209 is relatively too thick as compared to Co layer 208 and TiN layer 210, there is risk of increasing the sheet resistance (Rs). Accordingly, Ti layer 209 can be formed thinly formed at a predetermined thickness. Also, Ti layer 209 and TiN layer 210 forming processes can continuously be performed within the same depositing chamber or within separate depositing chambers.

As illustrated in example FIG. 2F, a first rapid thermal process (RTP) can be performed on and/or over substrate 200 to form CoSi layer on and/or over gate electrode 203 and the surfaces of source region 205 and drain region 206. Herein, the first thermal process can be performed at a temperature range of between 400 to 500 degrees C. Then, after the first rapid thermal process is complete, the silicide reaction is not initiated so that the non-reacted Co layer, Ti layer, and TiN layer can be sequentially removed. At this time, the non-reacted Co layer and Ti layer are removed by way of spacer 204 using a wet etch process that includes a mixture of H₂, SO₄, H₂O₂ or a mixing solution of NH₄OH, H₂O₂, H₂O and a mixing solution of HCl, H₂O₂, H₂O. Then, a secondary rapid thermal process can be performed on and/or over substrate 200 to selectively form cobalt silicide layer 211 on and/or over the surfaces of gate electrode 203, source region 205, and drain region 206. At this time, the secondary thermal process can be performed at a temperature range of between 700 to 900 degrees C. In accordance with embodiments, because the contents of the native oxide on the silicon (Si) surface has the largest effect on the thickness of cobalt silicide layer 211, the thickness of the salicide layer formed in source region 205 and drain region 206 can be easily controlled in order to obtain a salicide layer 211 of 90 nm or less.

In accordance with embodiments, a method of fabricating a semiconductor device in which the amount of oxide can be provided at a thickness range of between 0 um to 8 um, which can have an effect on the thickness of the salicide. Therefore, the thickness of the salicide can be controlled without breaking the shallow junction to diminish or otherwise eliminate problems associated with leakage current. This may result in a semiconductor device having enhanced reliability and electrical characteristics.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming a gate insulating layer, a gate electrode layer, a spacer, a source and a drain over a substrate on which a predetermined lower structure is formed;
making an upper portion of the gate electrode layer and upper portions of the source and the drain an amorphous structure using a pre-amorphization implant process;
removing native oxide from the upper portion of the gate electrode layer and the upper portions of the source and the drain by performing a pre-cleaning process;
forming an oxide film over the upper portion of the gate electrode layer and the upper portions of the source and the drain; and
forming a salicide layer over an upper portion of the oxide film.

2. The method of claim 1, wherein the oxide film is formed having a thickness of between 0 um to 8 um.

3. The method of claim 2, wherein the oxide film is formed using atomic layer deposition.

4. The method of claim 1, wherein forming the salicide layer comprises:
forming a Co layer, a Ti layer, and a TiN layer on an upper portion of the oxide film;
forming a CoSi layer using a first thermal process;
removing a non-reacted Co layer, Ti layer, and TiN layer using a wet etch; and
forming a cobalt salicide layer using a second rapid thermal process.

5. The method of claim 4, wherein the first thermal process is performed in a temperature range of between approximately 400 to 500 degrees C. and the second thermal process is performed in a temperature range of between 700 to 900 degrees C.

6. An apparatus comprising:
a gate insulating layer, a gate electrode layer, a spacer, a source and a drain formed over a substrate on which a predetermined lower structure is formed, wherein an upper portion of the gate electrode layer and upper portions of the source and the drain are formed as an amorphous structure using a pre-amorphization implant process;
an oxide film formed over the upper portion of the gate electrode layer and the upper portions of the source and the drain; and
a salicide layer formed over an upper portion of the oxide film.

7. The apparatus of claim 6, wherein the oxide film has a thickness of between 0 um to 8 um.

8. The apparatus of claim 7, wherein the oxide film is formed using atomic layer deposition.

9. A method comprising:
forming a device isolating layer over a semiconductor substrate;
forming a gate insulating layer over an active area defined by the device isolating layer;
forming a gate electrode over the semiconductor substrate;
forming source and drain regions;
amorphisizing an upper portion of the gate electrode layer and upper portions of the source and the drain regions;
forming an oxide layer having a thickness range of between 0 um to 8 um over the substrate;
sequentially forming Co, Ti, and TiN layers over the oxide film;
forming CoSi over the gate electrode and the source and drain regions using a first rapid thermal process;
removing a non-reacted Co layer, Ti layer, and TiN layer; and then
forming a cobalt salicide layer using a second rapid thermal process.

10. The method of claim 9, wherein the gate electrode is formed by depositing a material layer over the gate insulating layer and patterning the polysilicon material layer.

11. The method of claim 10, wherein the material layer is deposited using CVD.

12. The method of claim 11, wherein the material layer comprises polysilicon.

13. The method of claim 9, further comprising forming a spacer adjacent to sides of the gate electrode layer and the gate insulating layer prior to forming the source and drain regions.

14. The method of claim 9, wherein the source and drain regions are formed by formed by implanting a Group III or Group V ion using the gate electrode layer as a mask

15. The method of claim 9, wherein the upper portion of the gate electrode layer and upper portions of the source and the drain regions are amorphisized using a pre-amorphization implant process.

16. The method of claim 15, wherein during the pre-amorphization implant process ions from at least one of Ge, N₂, Ar and As are implanted.

17. The method of claim 9, further comprising the step of performing a wet cleaning process over the substrate using a HF solution to remove native oxide prior to forming an oxide film.

18. The method of claim 9, wherein the oxide layer is formed using atomic layer deposition.

19. The method of claim 9, wherein the first rapid thermal process is conducted at a temperature range of between 400 to 500 degrees C.

20. The method of claim 9, wherein the second rapid thermal process is performed at a temperature range of between 700 to 900 degrees C.
